(19) United States
(12) Patent Application Publication
(10) Pub. No.: US 2017/0254853 A1
(43) Pub. Date: Sep. 7, 2017

(54) INFORMATION PROCESSING DEVICE, INFORMATION PROCESSING METHOD, AND RECORDING MEDIUM

(71) Applicant: NEC Corporation, Tokyo (JP)

(72) Inventors: Yuichi IMAMURA, Tokyo (JP); Junichi MIYAMOTO, Tokyo (JP); Shingo TAKAHASHI, Tokyo (JP); Sho OHTANI, Tokyo (JP)

(73) Assignee: NEC Corporation, Tokyo (JP)

(21) Appl. No.: 15/505,417

(22) PCT Filed: Sep. 2, 2015
(86) PCT No.: PCT/JP2015/004463

§ 371 Date: Feb. 21, 2017

(30) Foreign Application Priority Data
Sep. 5, 2014 (JP) 2014-181340

(51) Int. Cl. G01R 31/36; H02J 3/32; H02J 7/00; H01M 10/44; H01M 10/48

(52) U.S. Cl. CPC G01R 31/36; H01M 10/44; H01M 10/48; H02J 7/007; H02J 3/32

(57) ABSTRACT

An information processing device according to the present invention includes: a reception unit which receives a state of an electricity storage unit which stores electric power; a charge and discharge control unit which controls charging in a charging period that includes a first period in which charging is performed from a second lower-limit voltage to a first lower-limit voltage and a second period in which charging is performed from the first lower-limit voltage to a first upper-limit voltage; and a capacity computation unit which calculates a capacity of the electricity storage unit, based on the state in the second period.

### TECHNICAL FIELD

The present invention relates to control of an electric power storage device that stores (charges) and discharges electric power, and relates particularly to an information processing device that measure a state of an electric power storage device, an electricity storage information processing method, and a recording medium.

### BACKGROUND ART

Recent years have seen an improvement in energy density of storage batteries (secondary cells) such as lithium-ion batteries. As a result, storage batteries are utilized in various fields. In addition, along with an increase in volume energy density of storage batteries and a decrease in electric power consumption of devices, size reduction and performance improvement of portable devices such as cellular phones are achieved. Alternatively, based on an improvement in energy weight density of storage batteries, an increase in moving distance of electric motor vehicles and the like are realized. Furthermore, stationary storage batteries have a function of providing electric power during daytime by using electric power charged by low-cost nighttime electric power and begin to be used in ordinary households.

Generally, the storage battery, when discharged, has a reduced battery capacity and, when charged, has an increased battery capacity. In describing a storage battery of an electric motor vehicle, for example, as an electric motor vehicle runs, the remaining capacity of the battery decreases and, in accordance with a decrease in the remaining capacity, the remaining cruisable distance decreases. Alternatively, in describing a household storage battery, for example, a storage battery provides electric power such as for a vacuum cleaner, a washing machine, and a TV (television), and reduces a residual quantity (SOC: state of charge) of the storage battery by an amount of electric power used for the provision. In addition, for example, a storage battery turns off (reduces) display of LED (light emitting diode) of an indicator that indicates a residual quantity in accordance with the residual quantity. The turning-off of light informs a user of a decrease in battery residual quantity.

Furthermore, when a storage battery is repeatedly charged and discharged, the full capacity of the storage battery itself decreases. For accurate calculation of an SOC, periodical determination of the capacity of the storage battery is needed. Furthermore, accurate measurement of the capacity leads to accurate calculation of the SOC. For example, by using an accurate SOC, a user can realize running of an electric motor vehicle in accordance with a plan.

Accordingly, a technique of calculating an accurate actual capacity of a storage battery is employed (e.g., refer to PTL 1).

The technique in PTL 1 determines an early-period actual capacity on the basis of a charge capacity from a completely discharged state to a fully charged state. Note that the technique described in PTL 1 assumes a case where a discharge voltage has decreased to a predetermined value (e.g., about 3 V) as being completely discharged.

### CITATION LIST

### Patent Literature

[PLT 1] Japanese Laid-open Patent Publication No. 2013-247045

### SUMMARY OF INVENTION

### Technical Problem

Generally, a stationary storage battery, such as a household storage battery, discharges at various amounts of electric power on the basis of a connected load situation. Furthermore, a stationary storage battery is often installed outdoors. Therefore, a stationary storage battery is exposed to environment at minus temperatures in the winter season and above 40° C. in the summer season. In such environment, the complete discharge of the storage battery as in the technique described in PTL 1 is difficult.

The reason will be described below.

Internal resistance of a storage battery, such as a lithium-ion battery, greatly changes on the basis of an environment temperature and a degree of deterioration. In other words, a voltage drop based on internal resistance (R) of a storage battery and a discharge current value (I) (i.e., based on IR component) varies depending on the environment temperature and the degree of deterioration. Therefore, the technique described in PTL 1, which determines a discharged state on the basis of the same final voltage, may possibly determine a state in which a remaining capacity is left as a completely discharged state that reaches a final voltage. Based on charging from this state to a fully charged state, the technique described in PTL 1 is unable to measure an accurate battery capacity. Thus, the to technique described in PTL 1 has a problem of not being able to measure an accurate battery capacity at times.

An object of the present invention is to provide an information processing device, an information processing method, and a recording medium for solving the foregoing problem and measuring an accurate full charge capacity of a storage battery.

### Solution to Problem

An information processing device according to one aspect of the present invention includes: reception means for receiving a state of electricity storage means for storing electric power; charge and discharge control means for controlling charging in a charging period that includes a first period in which charging is performed from a second lower-limit voltage to a first lower-limit voltage and a second period in which charging is performed from the first lower-limit voltage to a first upper-limit voltage; and capacity computation means for calculating a capacity of the electricity storage means, based on the state in the second period.

An information processing device according to one aspect of the present invention includes: electricity storage means for storing electric power; reception means for receiving a state of the electricity storage means; charge and discharge control means for controlling charging in a charging period that includes a first period in which charging is performed from a second lower-limit voltage to a first lower-limit voltage and a second period in which charging is performed from the first lower-limit voltage to a first upper-limit voltage; and capacity computation means for calculating a capacity of the electricity storage means, based on the state in the second period.

An information processing method according to one aspect of the present invention includes: receiving a state of electricity storage means for storing electric power; controlling charging of the electricity storage means in a charging period that includes a first period in which charging is performed from a second lower-limit voltage to a first lower-limit voltage and a second period in which charging is performed from the first lower-limit voltage to a first upper-limit voltage; and calculating a capacity of the electricity storage means, based on the state in the second period.

A computer readable non-transitory recording medium according to one aspect of the present invention records a program. The program causes a computer to execute: processing of receiving a state of electricity storage means for storing electric power; processing of controlling charging of the electricity storage means in a charging period that includes a first period in which charging is performed from a second lower-limit voltage to a first lower-limit voltage and a second period in which charging is performed from the first lower-limit voltage to a first upper-limit voltage; and processing of calculating a capacity of the electricity storage means, based on the state in the second period.

### Advantageous Effects of Invention

Based on the present invention, it is possible to provide an advantageous effect of accurately measuring a full charge capacity.

### BRIEF DESCRIPTION OF DRAWINGS

FIG. 1 is a block diagram illustrating an example of a construction of an information processing device according to a first example embodiment of the present invention;

FIG. 2 is a diagram illustrating an example of the charging and discharging for capacity measurement according to the first example embodiment;

FIG. 3 is a flowchart illustrating an example of processing of the information processing device according to the first example embodiment;

FIG. 4 is a diagram illustrating comparison between measurement results by the information processing device according to the first example embodiment and measurement results by a general device;

FIG. 5 is a block diagram illustrating another example of a construction of an information processing device according to the first example embodiment;

FIG. 6 is a block diagram illustrating another example of a construction of an information processing device according to the first example embodiment;

FIG. 7 is a block diagram illustrating an example of a construction of an information processing device according to a second example embodiment;

FIG. 8 is a diagram illustrating an example of the charging and discharging for the capacity measurement according to the second example embodiment;

FIG. 9 is a flowchart illustrating an example of processing of the information processing device according to the second example embodiment;

FIG. 10 is a diagram illustrating comparison between measurement results by the information processing device according to the second example embodiment and measurement results by a general measurement device;

FIG. 11 is a diagram illustrating comparison between measurement results by the information processing device according to the second example embodiment and measurement results by a general measurement device;

FIG. 12 is a diagram illustrating comparison between measurement results by the information processing device according to the second example embodiment and measurement results by a general measurement device;

FIG. 13 is a block diagram illustrating an example of a construction of an information processing device according to a third example embodiment;

FIG. 14 is a diagram illustrating an example of the charging and discharging for capacity measurement according to the third example embodiment;

FIG. 15 is a flowchart illustrating an example of processing of the information processing device according to the third example embodiment; and

FIG. 16 is a block diagram illustrating another example of a construction of an information processing device according to the first example embodiment.

### DESCRIPTION OF EMBODIMENTS

Hereinafter, example embodiments of the present invention will be described through the use of the drawings. Note that each drawing illustrates an example embodiment of the present invention. However, the present invention is not limited to what are indicated in the drawings. Furthermore, in the drawings, the same signs are given to the same constructions, and redundant descriptions thereof will sometimes be omitted as appropriate.

Furthermore, in the drawings used for the following description, portions of constructions not relevant to descriptions of the present invention are sometimes omitted and are not illustrated.

### First Example Embodiment

[Description of Construction]

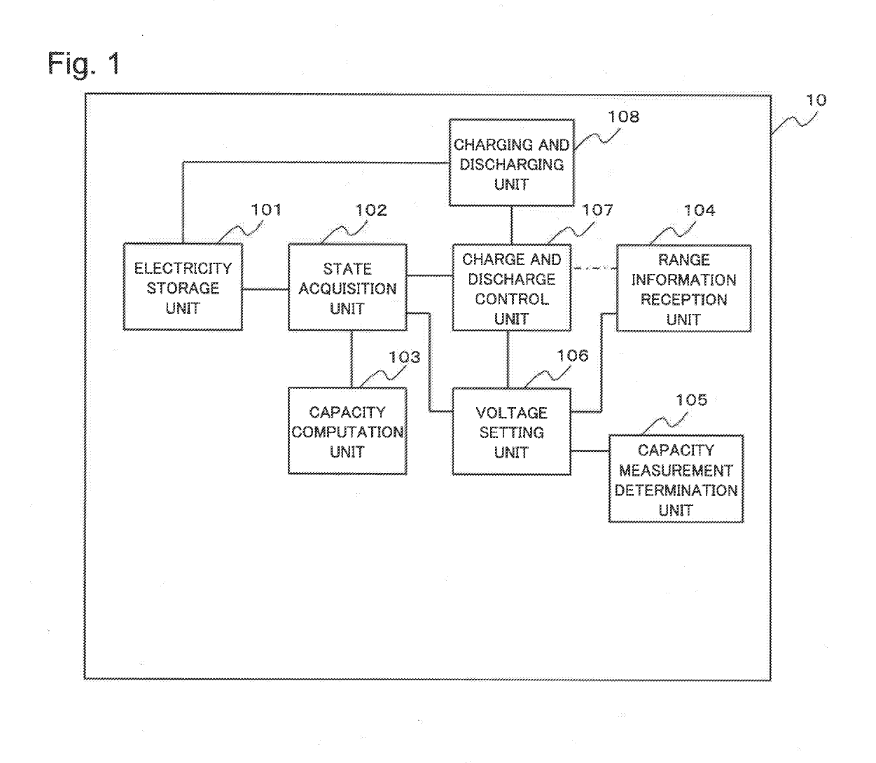

FIG. 1 is a block diagram illustrating an example of a construction of an information processing device 10 according to a first example embodiment of the present invention.

The information processing device 10 includes an electricity storage unit 101, a state acquisition unit 102, a capacity computation unit 103, a range information reception unit 104, a capacity measurement determination unit 105, a voltage setting unit 106, a charge and discharge control unit 107, and a charging and discharging unit 108.

The electricity storage unit 101 includes an electric power storage device that is not illustrated. Here, the electric power storage device is not particularly restricted. The electric power storage device is, for example, a secondary cell (a lithium-ion battery, a lead storage battery, a nickel-hydrogen battery, and the like) or an electric double layer capacitor. The electricity storage unit 101 may include one electric power storage device or a plurality of electric power storage devices connected in series or parallel. The electricity storage unit 101 is connected to an electric power supply device (e.g., an electric condenser) and an electric power-consuming device (e.g., a load device) which are not illustrated, and performs the charging and discharging of electric power.

The state acquisition unit 102 measures information (e.g., voltage electric current, and temperature) representing a state of the electricity storage unit 101. More specifically, the state acquisition unit 102 includes a voltage measuring instrument, an electric current measuring instrument, and/or a temperature measuring instrument which are not illustrated. In addition, the state acquisition unit 102, using the measuring instruments included therein, measures a physical quantity regarding the electric power storage device included in the electricity storage unit 101 (e.g., the cell voltage or total voltage of a storage battery, the charging current or discharging current of the storage battery, or the temperature of the electricity storage unit 101). Then, the state acquisition unit 102 sends (notifies) the measured state information regarding the electricity storage unit 101 to the capacity computation unit 103, the voltage setting unit 106, and the charge and discharge control unit 107. Note that the timing of the measurement and the timing of the sending by the state acquisition unit 102 are not particularly restricted. For example, the state acquisition unit 102 may, regularly or at predetermined time intervals, measure the state information about the electricity storage unit 101 and send the measured state information to the capacity computation unit 103 and the charge and discharge control unit 107. Alternatively, the state acquisition unit 102 may, in response to a request from the capacity computation unit 103 or the charge and discharge control unit 107, measure the state information about the electricity storage unit 101 and send the state information to the capacity computation unit 103 or the charge and discharge control unit 107. Alternatively, the state acquisition unit 102 may measure the state information about the electricity storage unit 101 at predetermined time intervals and send the measured state information in response to a request from the capacity computation unit 103 or the charge and discharge control unit 107. Note that the state acquisition unit 102 may acquire (receive) the state of the electricity storage unit 101 from a voltage measuring instrument, an electric current measuring instrument, and/or a temperature measuring instrument which are not illustrated and which are provided outside the information processing device 10. In this case, the state acquisition unit 102 operates as a reception unit that receives the state of the electricity storage unit. Hereinafter, “the state acquisition unit 102 acquiring a state” and the like will sometimes be referred to as “the state acquisition unit 102 receiving a state”.

The capacity computation unit 103, using the state information, calculates the capacity (e.g., the SOC (state of charge) or the SOH (state of health)) of the electricity storage unit 101. The capacity computation unit 103 may store the calculated capacity (SOC, SOH, or the like) into a storage unit that is not illustrated. Hereinafter, the values calculated by the capacity computation unit 103, including SOC and the like, will be collectively referred to as “capacity”.

The range information reception unit 104 receives range information. The range information includes an upper-limit voltage of a voltage range in ordinary use (upper-limit voltage in use) and a lower-limit voltage of the voltage range in ordinary use (lower-limit voltage in use) of the electricity storage unit 101 as well as an upper-limit voltage (first upper-limit voltage) and a lower-limit voltage (first lower-limit voltage) of a voltage range of capacity measurement. Note that the range information reception unit 104 may simultaneously receive the voltage range in use and the voltage range of the capacity measurement or may receive them separately. Furthermore, the range information reception unit 104 may receive the voltage range of the capacity measurement not only once but a plurality of times.

The sending source of the range information is not particularly limited. For example, the range information reception unit 104 may receive the range information from a device operated by a user or a business operator of the information processing device 10 which is not illustrated. Furthermore, the range information reception unit 104 is not particularly restricted in terms of pathway of information. For example, the range information reception unit 104 may connect, via the Internet, to a device operated by a user. The range information reception unit 104 sends the received information to the voltage setting unit 106.

The capacity measurement determination unit 105 notifies the voltage setting unit 106 of whether measurement of the capacity of the electricity storage unit 101 is to be performed or not. The capacity measurement determination unit 105 may periodically notify the voltage setting unit 106 of whether measurement of the capacity is to be performed or not. Alternatively, the capacity measurement determination unit 105 may notify the voltage setting unit 106 of whether measurement of the capacity is to be performed or not on the basis of an instruction from a device operated by a user or a business operator that is not illustrated. Note that the capacity measurement determination unit 105 may notify the voltage setting unit 106 of “permission of measurement”, i.e., start of measurement, but not of “prohibition of measurement”. Therefore, hereinafter, the notification from the capacity measurement determination unit 105 will be referred to as “start-of-measurement notification”.

The voltage setting unit 106 receives from the range information reception unit 104 the range information (the first upper-limit voltage and the first lower-limit voltage as well as the upper-limit voltage in use and the lower-limit voltage in use). Furthermore, the voltage setting unit 106 receives the start-of-measurement notification from the capacity measurement determination unit 105. Furthermore, the voltage setting unit 106 receives the state information from the state acquisition unit 102. Then, the voltage setting unit 106 calculates a second lower-limit voltage on the basis of the range information and the state information.

Here, the second lower-limit voltage will be described.

The information processing device 10, at the time of measuring the capacity of the electricity storage unit 101, needs realization of a stable first lower-limit voltage as a starting point of measurement. More specifically, the information processing device 10 realizes a stable first lower-limit voltage by performing constant current-constant voltage (CCCV) charging up to the first lower-limit voltage. In order to realize the first lower-limit voltage from a voltage lower than the first lower-limit voltage by using the CCCV charging, the information processing device 10 needs to make an open-circuit voltage of the electricity storage unit 101 sufficiently lower than the first lower-limit voltage and then start the CCCV charging before realizing a stable first lower-limit voltage. Thus, the information processing device 10, before realizing the stable first lower-limit voltage, sets the voltage of the electricity storage unit 101 to the second lower-limit voltage as a starting point for performing the CCCV charging to the first lower-limit voltage (referred to as preliminary charging). Therefore, in the present example embodiment, the second lower-limit voltage is a “lower-side voltage (lower voltage)”, the first lower-limit voltage is an “intermediate voltage (middle voltage)”, and the first upper-limit voltage is an “upper-side voltage (upper voltage)”. The second lower-limit voltage will be further described later.

The voltage setting unit 106 sends the range information (the upper-limit voltage in use, the lower-limit voltage in use, the first upper-limit voltage, and the first lower-limit voltage) and information about the second lower-limit voltage to the charge and discharge control unit 107. Note that the charge and discharge control unit 107 may receive the range information from the range information reception unit 104.

Then, the voltage setting unit 106, on the basis of the start-of-measurement notification, notifies the charge and discharge control unit 107 of start of the measurement. Note that when the start-of-measurement notification includes the permission of the measurement, the voltage setting unit 106, when the measurement is to be performed, may notify the charge and discharge control unit 107 of start of the measurement. Alternatively, the charge and discharge control unit 107 may determine the reception of information, including the second lower-limit voltage, from the voltage setting unit 106 as being an instruction for start of the measurement.

The charge and discharge control unit 107 sends the acquired voltage information (the range information and the second lower-limit voltage) to the charging and discharging unit 108 and controls the charging and discharging of the electricity storage unit 101 by causing the charging and discharging unit 108 to charge or discharge the electricity storage unit 101.

The charging and discharging unit 108 charges and discharges the electricity storage unit 101 on the basis of the acquired voltage information. It is desirable that, in charging, the charging and discharging unit 108 perform the CCCV charging of the electricity storage unit 101. Note that the charging and discharging unit 108 may control the charging and discharging of the electricity storage unit 101 by controlling the connection between the electricity storage unit 101 and an electric condenser or load not illustrated.

Note that as for the information processing device 10 in the present example embodiment, the charging does not need to be limited to CCCV charging. For example, the information processing device 10, in charging, may use constant-power (CP) charging or pulse charging instead of the constant-current (CC) charging. Alternatively, the information processing device 10 may use variable-rate charging for the charging.

[Description of Operation]

Next, operations of the information processing device 10 will be described.

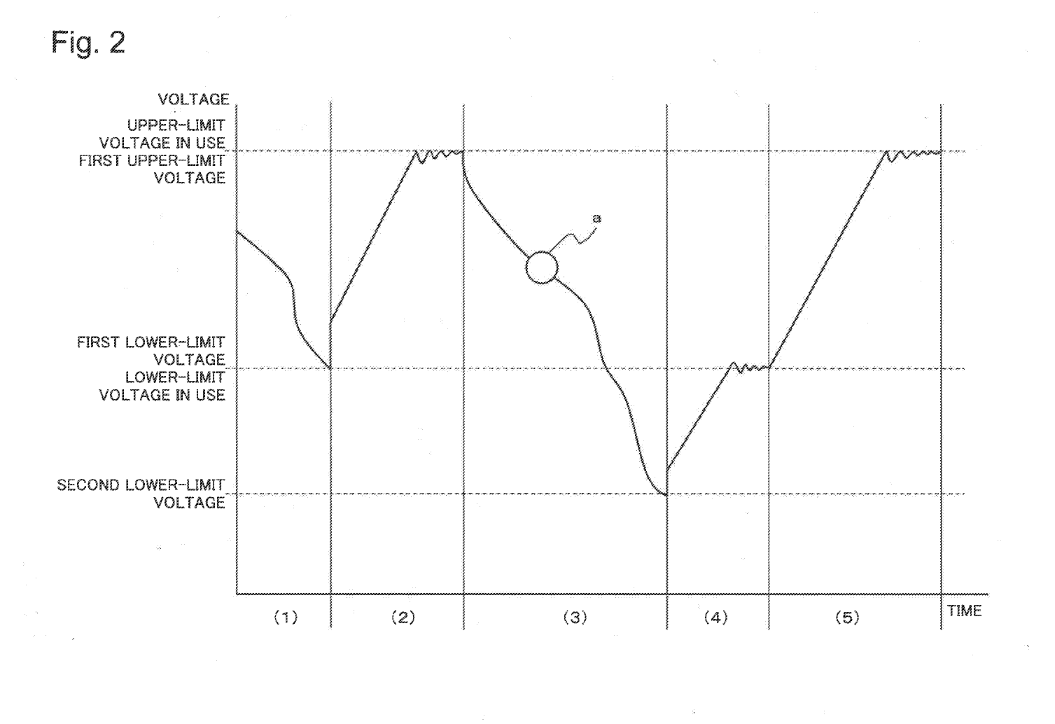

FIG. 2 is a diagram illustrating an example of the charging and discharging for capacity measurement according to the first example embodiment.

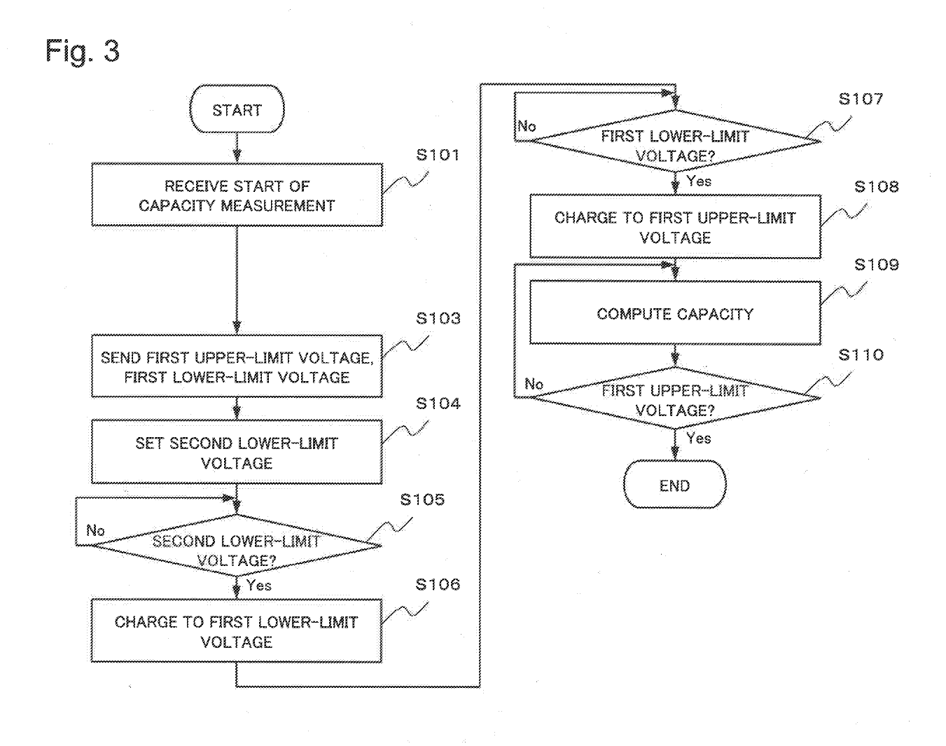

FIG. 3 is a flowchart illustrating an example of processing of the information processing device 10 according to the first example embodiment.

Note that FIG. 2 illustrates a case where the voltage range in ordinary use and the capacity measurement range are the same.

A time (1) illustrated in FIG. 2 corresponds to an ordinarily discharged state. Ordinarily, in the electricity storage unit 101, the voltage decreases according to changes in load. The charge and discharge control unit 107, on the basis of the state information from the state acquisition unit 102, instructs the charging and discharging unit 108 to perform the ordinary charging when the voltage of the electricity storage unit 101 reaches the ordinary lower-limit voltage in use.

A time (2) corresponds to an ordinarily charged state. Note that the voltage difference between the time (1) and the time (2) is a voltage difference based on the internal resistance of the rechargeable battery. The charging and discharging unit 108 performs the CCCV charging of the electricity storage unit 101. Therefore, a line that indicates the voltage in the time (2) illustrated in FIG. 2 is a straight line or a curve approximate to a straight line (hereinafter, collectively referred to as “substantially straight line”) up to the vicinity of the upper-limit voltage in use. When the voltage of the electricity storage unit 101 reaches the upper-limit voltage in use, the charge and discharge control unit 107 switches to the CV (constant voltage) charging. When a CV ending condition is satisfied, the charge and discharge control unit 107 instructs the charging and discharging unit 108 to stop charging. Here, the CV ending condition is, for example, one of the following conditions.

First condition: the charging current has become sufficiently small.
Second condition: a sufficient time has elapsed following the switch to the CV charging.
Third condition: both the first condition and the second condition are satisfied.
Fourth condition: a sufficient time has elapsed following the charging current becoming sufficiently small.
However, the CV ending condition in the present example embodiment is not limited to these.
After this, the electricity storage unit 101 discharges according to the load as in the time (1).

A time (3) corresponds to an ordinarily discharged state. However, at a point a in the time (3) in FIG. 2, the information processing device 10 detects start of the capacity measurement (step S101). For example, the capacity measurement determination unit 105 detects a periodical capacity measurement timing and orders the voltage setting unit 106 to start the measurement.

The voltage setting unit 106 sends voltages to be used in the measurement (the first upper-limit voltage and the first lower-limit voltage) to the charge and discharge control unit 107 (step S103).

Next, the voltage setting unit 106 calculates the second lower-limit voltage and sends information about the calculated second lower-limit voltage to the charge and discharge control unit 107 (step S104). The voltage setting unit 106 in the present example embodiment calculates a second lower-limit voltage that satisfies formula 1 illustrated below. More specifically, the voltage setting unit 106 calculates the internal resistance of the electricity storage unit 101 on the basis of the temperature included in the state information about the electricity storage unit 101 received from the state acquisition unit 102. Then, the voltage setting unit 106 calculates the second lower-limit voltage by using the internal resistance, the value of current in discharge, and the first lower-limit voltage.

The second lower-limit voltage≦(the first lower-limit voltage−(the internal resistance of the electricity storage unit 101×the discharge current value)−(the internal resistance of the electricity storage unit 101×the charge current value)) [Formula 1]

However, the technique for determining the second lower-limit voltage of the voltage setting unit 106 does not need to be limited to the formula 1. It suffices that the voltage setting unit 106 uses a technique suitable to calculate the capacity of the electricity storage unit 101.

The charge and discharge control unit 107 causes the charging and discharging unit 108 to discharge the electricity storage unit 101 until the electricity storage unit 101 reaches the second lower-limit voltage (No in step S105).

A time (4) corresponds to a preliminary charging state.

When the voltage of the electricity storage unit 101 reaches the second lower-limit voltage (Yes in step S105), the charge and discharge control unit 107 instructs the charging and discharging unit 108 to perform the CCCV charging up to the first lower-limit voltage (step S106).

The charge and discharge control unit 107 waits (No in step S107) until the charge voltage reaches the first lower-limit voltage.

A time (5) corresponds to a capacity calculation state.

When charging is performed to the first lower-limit voltage (Yes in step S107), the charge and discharge control unit 107 instructs the charging and discharging unit 108 to perform the CCCV charging up to the first upper-limit voltage of the electricity storage unit 101 (step S108).

The capacity computation unit 103, on the basis of the current having flown between the first lower-limit voltage and the first upper-limit voltage, calculates a measured value of the capacity (full charge capacity) of the electricity storage unit 101 (step S109). For example, the capacity computation unit 103 calculates the measured value of the capacity by integrating the current included in the state information received from the state acquisition unit 102 (e.g., by a current integration method).

[Measurement Results]

Next, measurement results by the information processing device 10 in the present example embodiment and a general measurement device (e.g., a device that performs constant-current (CC: constant current) discharging to the first lower-limit voltage and then performs CCCV charging to the first upper-limit voltage) will be described.

The electricity storage unit 101 used in this measurement was a lithium-ion secondary battery. Furthermore, the upper-limit voltage in use and the first upper-limit voltage were 4.1 V, the lower-limit voltage in use and the first lower-limit voltage were 3.0 V, and the second lower-limit voltage was 2.5 V.

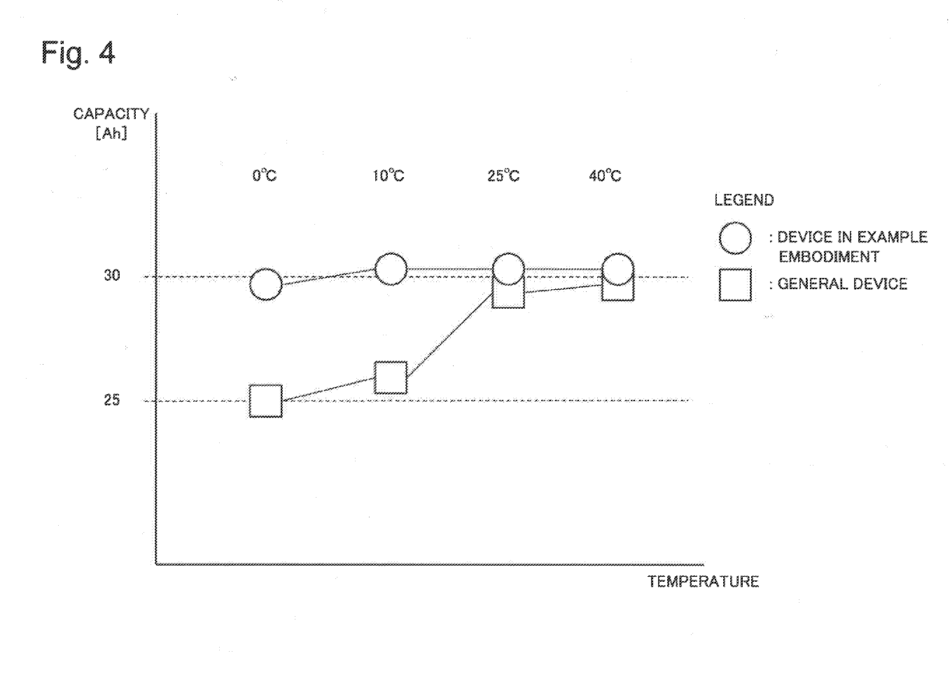

FIG. 4 is a diagram illustrating comparison between measurement results by the information processing device 10 according to the present example embodiment and measurement results by a general measurement device. As illustrated in FIG. 4, with the general measurement device, the measured value of the capacity became smaller as the temperature became lower. In other words, with the general measurement device, errors became larger when the temperature was lower. On the other hand, as for the measurement results by the information processing device 10 in the present example embodiment, such a temperature dependency as in the general measurement device was not observed and accurate measured values of the capacity was obtained.

### Description of Advantageous Effects

Thus, the present example embodiment can obtain an advantageous effect that the full charge capacity is accurately measured.

The reasons are as follows.

In order to stably realize the first lower-limit voltage for use for measurement, the voltage setting unit 106 calculates the second lower-limit voltage that is lower than the first lower-limit voltage. Then, the charge and discharge control unit 107 discharges the electricity storage unit 101 to the second lower-limit voltage and, afterwards, by using the charging and discharging unit 108, performs the CCCV charging of the electricity storage unit 101 to the first lower-limit voltage. Therefore, the first lower-limit voltage, which is the starting point for the measurement, is stable. In addition, the charge and discharge control unit 107, using the charging and discharging unit 108, performs the CCCV charging of the electricity storage unit 101 to the first upper-limit voltage and measures the capacity of the electricity storage unit 101. Thus, the information processing device 10 can measure the capacity by using the stable first lower-limit voltage.

[Modification 1]

The information processing device 10 described as above is constructed as follows.

For example, each of component units of the information processing device 10 may be constructed of hardware circuit.

Furthermore, the information processing device 10 may be constructed by using a plurality of information processing devices obtained by connecting each of component units of the information processing device 10 via a network or a bus.

For example, the information processing device 10 may have the range information reception unit 104 as a separate device, and may, prior to processing, receive necessary information (of the upper-limit voltage in use, the lower-limit voltage in use, the first upper-limit voltage, and the first lower-limit voltage) and store the information to operate. Furthermore, the information processing device 10 may have the capacity measurement determination unit 105 as a separate device and, on the basis of an order from that device, execute capacity measurement. Furthermore, the information processing device 10 may control the electricity storage unit 101 that is installed as a separate device.

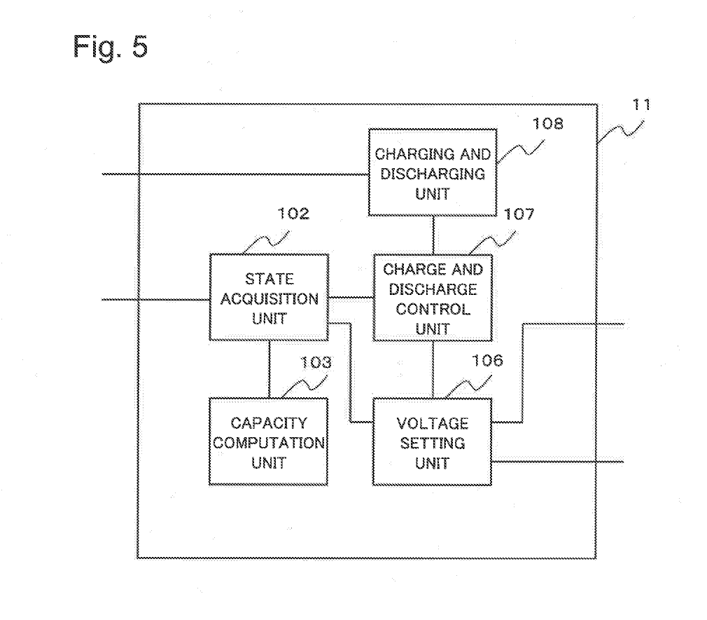

FIG. 5 includes an example of a construction of an information processing device 11 according to of the present modification.

The information processing device 11 includes the state acquisition unit 102, the capacity computation unit 103, the voltage setting unit 106, the charge and discharge control unit 107, and the charging and discharging unit 108. Each of the constructions of the information processing device 11 operates in substantially the same manner as each of the information processing device 10. Therefore, detailed description of the constructions and operations will be omitted.

However, the state acquisition unit 102 receives information that represents the state of an electricity storage unit not illustrated which corresponds to the electricity storage unit 101 in FIG. 1.

The voltage setting unit 106 receives the range information from a range information reception unit not illustrated which corresponds to the range information reception unit 104 in FIG. 1. Furthermore, the voltage setting unit 106 receives the start-of-measurement notification from a capacity measurement determination unit not illustrated which corresponds to the capacity measurement determination unit 105 in FIG. 1.

The charging and discharging unit 108 charges and discharges an electricity storage unit not illustrated, on the basis of an order from the charge and discharge control unit 107.

The information processing device 11 constructed in this manner can obtain substantially the same advantageous effects as the information processing device 10.

The reason is that the information processing device 11 can realize substantially the same functions as the information processing device 10.

[Modification 2]

Furthermore, in the information processing device 10, constructions, excluding the state acquisition unit 102, the capacity computation unit 103, and the charge and discharge control unit 107, may be constructed of separate devices.

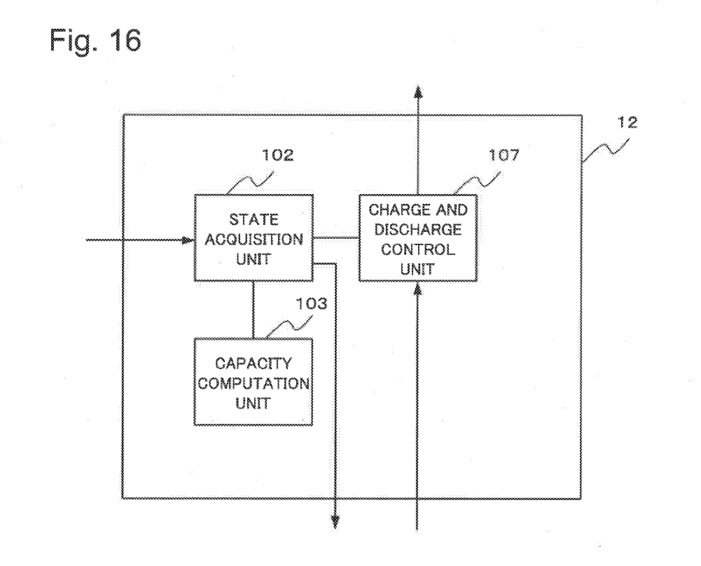

FIG. 16 includes an example of a construction of an information processing device 12 according to the present modification.

The information processing device 12 includes the state acquisition unit 102, the capacity computation unit 103, and the charge and discharge control unit 107. Each of the constructions of the information processing device 12 operates in substantially the same manner as the information processing device 10. In other words, the state acquisition unit 102 acquires or receives the state of the electricity storage unit 101. The charge and discharge control unit 107 controls the charging and discharging of the charging unit 101 by using the charging and discharging unit 108 on the basis of the information from the voltage setting unit 106. Then, the capacity computation unit 103 calculates the capacity of the electricity storage unit 101 on the basis of the state acquired by the state acquisition unit 102.

The information processing device 12 constructed in this manner can obtain substantially the same advantageous effects as the information processing device 10.

The reason is that the information processing device 12 can realize substantially the same functions as the information processing device 10.

Note that the information processing device 12 is a minimum construction of the present invention.

[Modification 3]

Furthermore, in the information processing device 10, the information processing device 11, and the information processing device 12, the plurality of component units of each device may be constructed of one piece of hardware. Hereinafter, for the sake of convenience in description, in the case of description common to the information processing device 10, the information processing device 11, and the information processing device 12, description will be made as that for the information processing device 10.

Furthermore, the information processing device 10 may be realized as a computer device that includes a CPU (central processing unit), a ROM (read only memory), and a RAM (random access memory). The information processing device 10 may be realized as a computer device that includes, in addition to the foregoing constructions, an input and output connection circuit (IOC: input and output circuit) and a network interface circuit (NIC: network interface circuit).

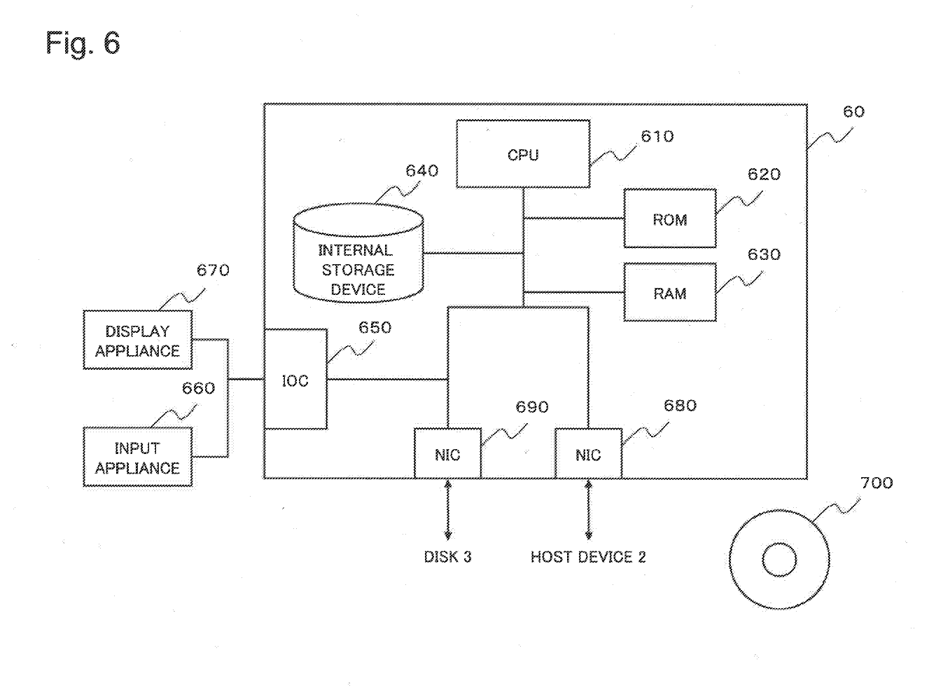

FIG. 6 is a block diagram illustrating an example of a construction of an information processing device 60 according to the present modification.

The information processing device 60 includes a CPU 610, a ROM 620, a RAM 630, an internal storage device 640, an IOC 650, and an NIC 680, and constitutes a computer device.

The CPU 610 reads a program from the ROM 620. Then, the CPU 610, on the basis of the read program, controls the RAM 630, the internal storage device 640, the IOC 650, and the NIC 680. Subsequently, the computer that includes the CPU 610 controls these constructions and realizes various functions as the state acquisition unit 102, the capacity computation unit 103, the voltage setting unit 106, and the charge and discharge control unit 107 illustrated in FIG. 1 and FIG. 5. Furthermore, the computer that includes the CPU 610 may realizes at least one or more of the functions as the electricity storage unit 101, the range information reception unit 104, the capacity measurement determination unit 105, or the charging and discharging unit 108 illustrated in FIG. 1. Alternatively, the computer that includes the CPU 610 controls these constructions and realizes the functions as the state acquisition unit 102, the capacity computation unit 103, and the charge and discharge control unit 107 illustrated in FIG. 16.

The CPU 610, when realizing the various functions, may use the RAM 630 or the internal storage device 640 as a temporary memory for programs.

Furthermore, the CPU 610 may read programs contained in the storage medium 700 in which programs are stored so as to be readable by the computer, by using a storage medium reading device not illustrated. Alternatively, the CPU 610 may receive a program from an external device not illustrated, via the NIC 680, and store the program into the RAM 630, and operate on the basis of the stored programs.

The ROM 620 stores programs that the CPU 610 executes and fixed data. The ROM 620 is, for example, a P-ROM (programmable ROM) or a flash ROM.

The RAM 630 temporarily stores programs that the CPU 610 executes and data. The RAM 630 is, for example, a D-RAM (dynamic RAM).

The internal storage device 640 stores programs and data that the information processing device 60 stores for a long period. Furthermore, the internal storage device 640 may operate as a temporary storage device of the CPU 610. The internal storage device 640 is, for example, a hard disk device, a magneto-optical disk device, an SSD (solid state drive), and a disk array device.

The ROM 620 and the internal storage device 640 are non-transitory storage media. On the other hand, the RAM 630 is a transitory storage medium. In addition, the CPU 610 is able to operate on the basis of programs stored in the ROM 620, the internal storage device 640, or the RAM 630. In other words, the CPU 610 is able to operate by using a non-transitory storage medium or a transitory storage medium.

The IOC 650 interfaces data between the CPU 610, and the input appliance 660 and the display appliance 670. The IOC 650 is, for example, an IO interface card or a USB (universal serial bus) card.

The input appliance 660 is an appliance that receives an input order from an operator of the information processing device 60. The input appliance 660 is, for example, a keyboard, a mouse, or a touch panel. The input appliance 660 may operate as the range information reception unit 104 or the capacity measurement determination unit 105.

The display appliance 670 is an appliance that displays information to an operator of the information processing device 60. The display appliance 670 is, for example, a liquid crystal display.

The NIC 680 relays exchange of data with an external device which is not illustrated via a network. The NIC 680 may operate as the range information reception unit 104. The NIC 680 is, for example, a LAN (local area network) card. The NIC 680 may operate as the range information reception unit 104 or the capacity measurement determination unit 105.

The information processing device 60 constructed in this manner can obtain substantially the same advantageous effect as the information processing device 10.

The reason is that the CPU 610 of the information processing device 60 can realize substantially the same functions as the information processing device 10 on the basis of programs.

### Second Example Embodiment

In the description of the first example embodiment, the voltage range in ordinary use and the voltage range of the capacity measurement are the same. However, the voltage range in ordinary use and the capacity measurement range may be different. Therefore, an example embodiment in which the voltage range in ordinary use and the capacity measurement range are different will be described as a second example embodiment. In the present example embodiment, too, the second lower-limit voltage is a “lower-side voltage (lower voltage)”, the first lower-limit voltage is an “intermediate voltage (middle voltage)”, and the first upper-limit voltage is an “upper-side voltage (upper voltage)”.

Note that in the present example embodiment, calculation is also performed with regard to the deterioration rate.

Hereinafter, the second example embodiment according to the present invention will be described with reference to the drawings.

[Description of Construction]

First, a construction of an information processing device 20 according to the second example embodiment will be described.

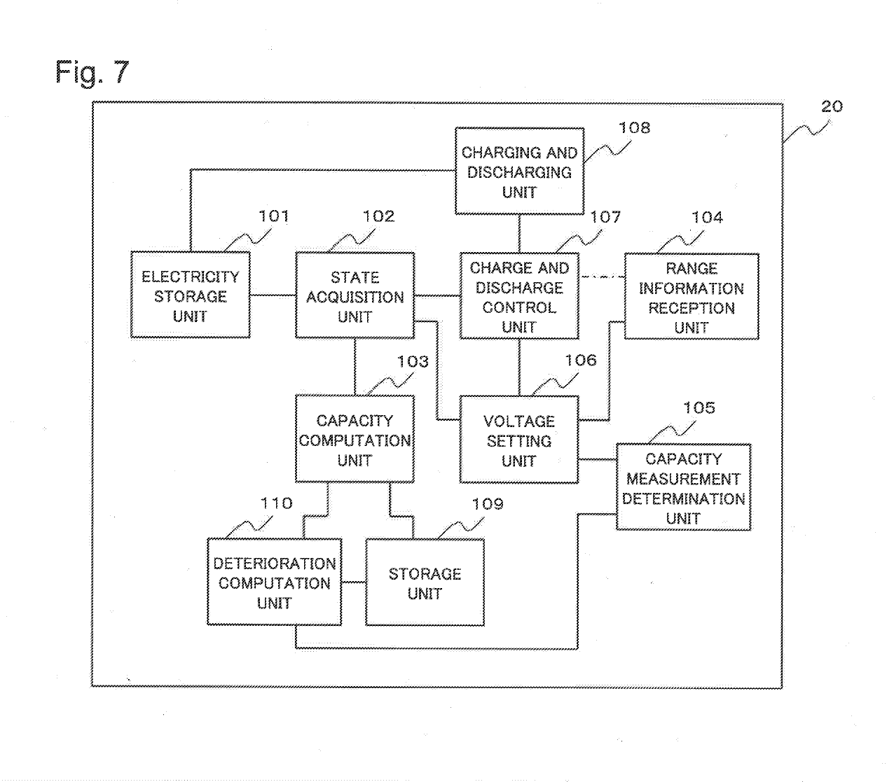

FIG. 7 is a block diagram illustrating an example of a construction of the information processing device 20 according to the second example embodiment. The information processing device 20 includes a storage unit 109 and a deterioration computation unit 110 in addition to the constructions of the information processing device 10 of the first example embodiment. Hereinafter, for convenience in description, descriptions of constructions that operate substantially the same manner as in the first example embodiment will be omitted and operations particular to the present example embodiment will be described. Note that the information processing device 20 may be realized by using a computer illustrated in FIG. 6.

A capacity measurement determination unit 105 sends whether measurement of the capacity is to be performed or not to a deterioration computation unit 110 as well as to the voltage setting unit 106.

A storage unit 109 stores the capacity of the electricity storage unit 101 calculated by the capacity computation unit 103 and sends the stored capacity to the deterioration computation unit 110 as necessary. The storage unit 109 stores at least a first capacity (early capacity value).

The deterioration computation unit 110, after receiving a permission of measurement of the capacity from the capacity measurement determination unit 105, calculates a deterioration rate of the electricity storage unit 101 by using the measured value of the capacity calculated by the capacity computation unit 103 and the capacity stored in the storage unit 109 (e.g., an early capacity value). The deterioration computation unit 110 may calculate the deterioration rate based on the capacity at a predetermined time point which is stored in the storage unit 109.

Note that the deterioration computation unit 110 may store the calculated deterioration rate in the storage unit 109.

[Description of Operations]

Next, operations of the information processing device 20 will be described.

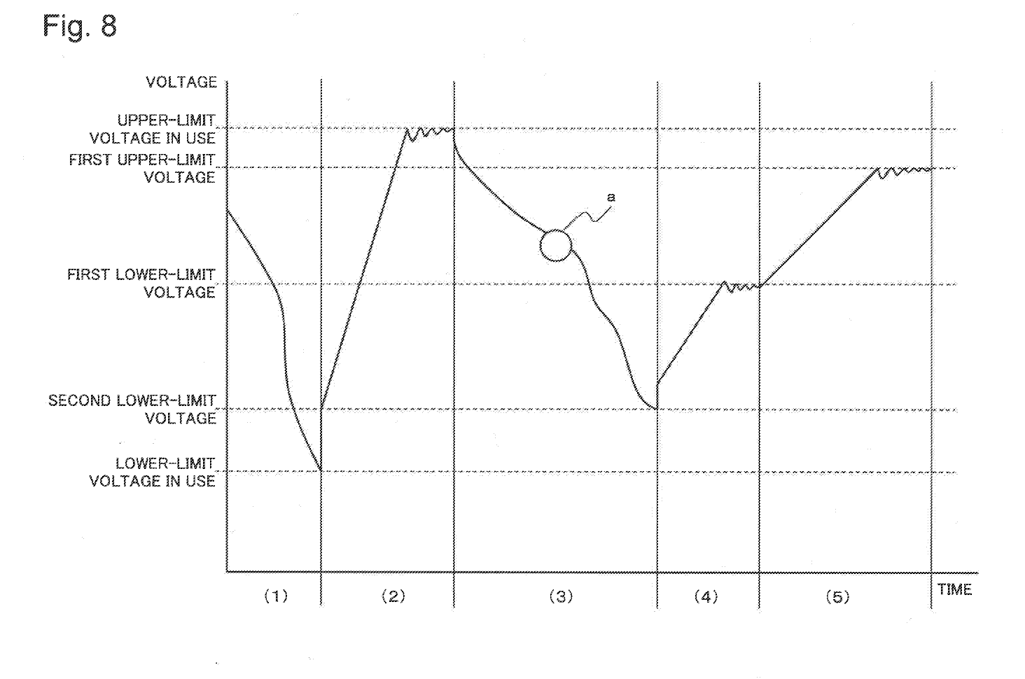

FIG. 8 is a diagram illustrating an example of the charging and discharging for the capacity measurement according to the second example embodiment. FIG. 8 is substantially the same, except that the upper-limit voltage in use and the first upper-limit voltage and also the lower-limit voltage in use and the first lower-limit voltage are each different.

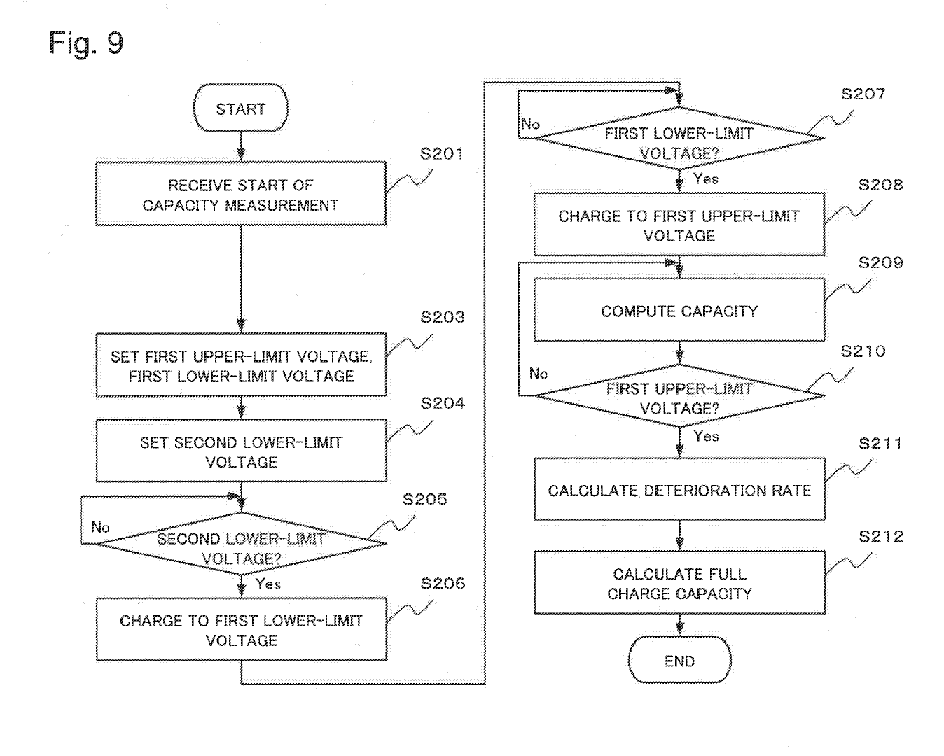

FIG. 9 is a flowchart illustrating an example of processing of the information processing device 20 according to the second example embodiment. In FIG. 9, operations from step S201 to step S210 are substantially the same operations as the operations from step S101 to S110. Therefore, hereinafter, descriptions of the same operations as in the first example embodiment will be omitted and operations different from those in the first example embodiment will be described.

First, steps S201 to S210 substantially the same as in the first example embodiment will be described.

In step S203, the voltage setting unit 106 sends to the charge and discharge control unit 107 the first upper-limit voltage received from the range information reception unit 104. However, the voltage setting unit 106 may calculate the first upper-limit voltage that satisfies formula 2 indicated below and send it to the charge and discharge control unit 107.

The first upper-limit voltage≧(the first lower-limit voltage+(the internal resistance of the electricity storage unit 101×the charge current value)) [Formula 2]

When, in step S204, the voltage of the electricity storage unit 101 is lower than the second lower-limit voltage, the charge and discharge control unit 107 may omit a discharging operation to the second lower-limit voltage in step S205. Furthermore, when it is desired that the capacity from the voltage (V_{now}) at the present time point to the first upper-limit voltage be measured, the information processing device 20 may execute an operation as follows. In other words, the voltage setting unit 106 assumes the voltage (V_{now}) at the present time point as a second lower-limit voltage and calculates the first lower-limit voltage that satisfies the formula 1. Then, it suffices that the capacity computation unit 103 measures a capacity between the calculated first lower-limit voltage and the first upper-limit voltage. Furthermore, in this case, too, the information processing device 20 can omit the discharging operation to the second lower-limit voltage of step S205.

Next, step S211 and the subsequent steps will be described.

The deterioration computation unit 110 applies the early capacity stored in the storage unit 109 and the determined measured value of the capacity (the capacity at the time point n) to formula 3 to calculate the deterioration rate (%)(step S211). Here, the storage unit 109 stores early capacities separate for each voltage range capable of being set as an early capacity.

The deterioration rate (%)=((the capacity at the time point n)/(the early capacity))×100 [Formula 3]

Furthermore, the deterioration computation unit 110 applies the early capacity (the measured capacity value between SOCs of 0% and 100% at the time of a new product) and the deterioration rate to formula 4 to calculate the full charge capacity (Ah) (step S212).

The full charge capacity (Ah)=the early capacity×the deterioration rate [Formula 4]

However, the deterioration computation unit 110 does not necessarily need to use the formula 4 but may use other methods to calculate the full charge capacity. For example, the deterioration computation unit 110, using a correspondence table between voltages and SOCs or the like, replaces the first lower-limit voltage and the first upper-limit voltage at which the capacity is measured with SOCs. Then, the deterioration computation unit 110 may calculate the full charge capacity on the basis of a proportional relation between the range of the replaced SOCs (and their capacities) and the range of SOC of the full charge capacity (SOCs of 0% to 100%).

The deterioration computation unit 110 may store the calculated deterioration rate and full charge capacity into the storage unit 109.

Note that the information processing device 20 of the present example embodiment does not need to use only the CCCV discharging in the charging. For example, the information processing device 20 may, instead of the CC charging, use the CP charging or the pulse charging. Alternatively, the information processing device 20 may use variable-rate charging for the charging.

[Measurement Results]

Next, measurement results by the information processing device 20 of the present example embodiment and a general measurement device (comparative art) will be described.

The storage battery used for the measurement results described below was a lithium-ion secondary battery. Furthermore, the upper-limit voltage in use was 4.1 V, the lower-limit voltage in use was 3.0 V, the first upper-limit voltage was 4.0 V, the first lower-limit voltage was 3.8 V, and the second lower-limit voltage was 3.3 V. Measurement was carried out every three months (April 1st, July 1st, October 1st, and January 1st of the following year). Here, the measurement on April 1st was measurement at the time of a new product in a factory. The other measurements were outdoor measurements.

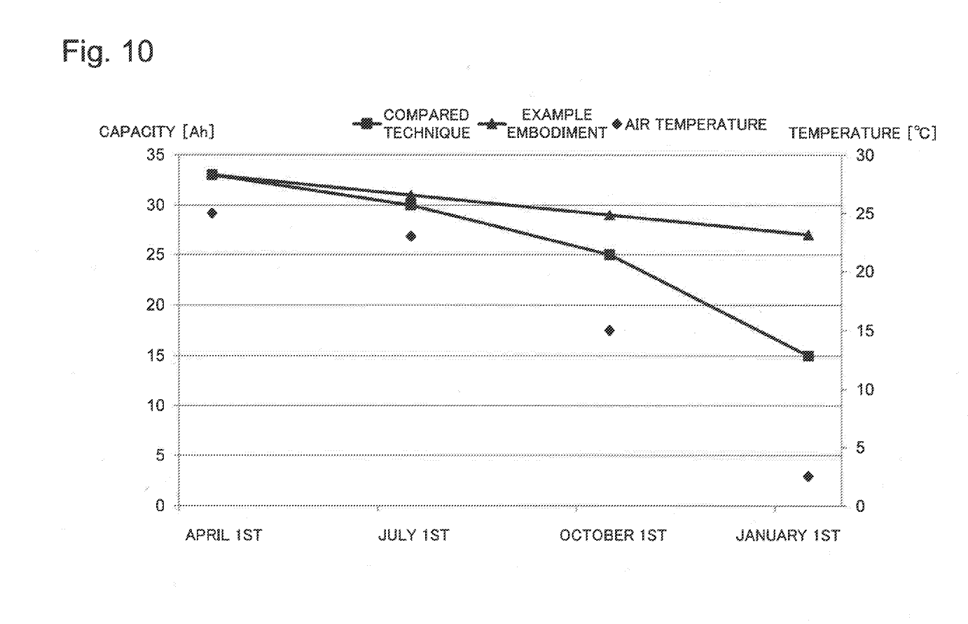

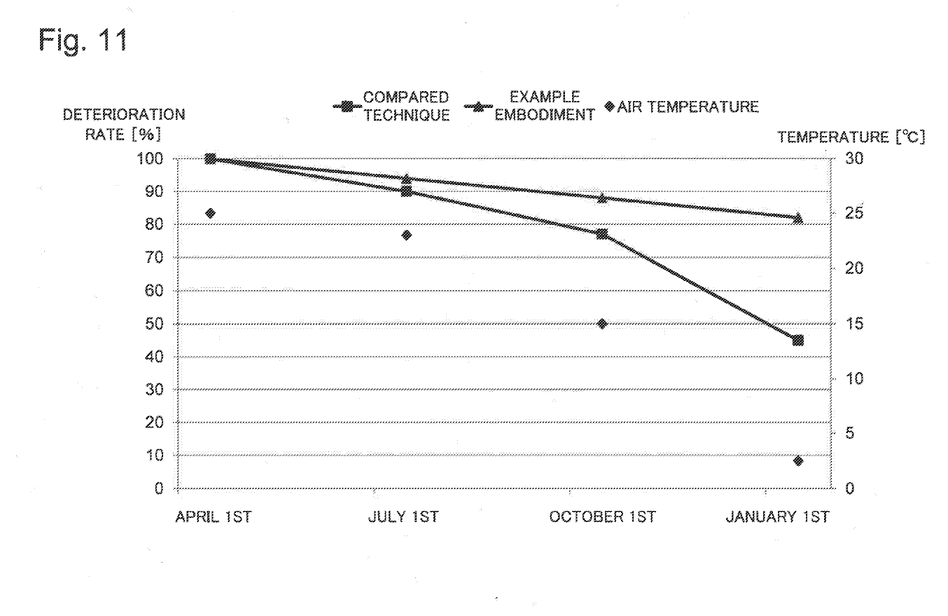

FIG. 10 is a diagram illustrating comparison of capacity measurement results. Furthermore, FIG. 11 is a diagram illustrating comparison of results of the deterioration rate.

As illustrated in FIG. 10 and FIG. 11, with the general measurement device, decreases in the capacity and the deterioration rate became large with elapse of time and decrease of temperature. This indicates that accurate capacity measurement was not executed on the basis of a change in temperature when the capacity was measured, increases of the internal resistance based on deterioration of the storage battery, and the like. On the other hand, measurement results of the information processing device 20 of the present example embodiment are less easily affected by temperature, internal resistance, and the like, and it is indicated that the information processing device 20 was able to measure a more accurate capacity than the general measurement device.

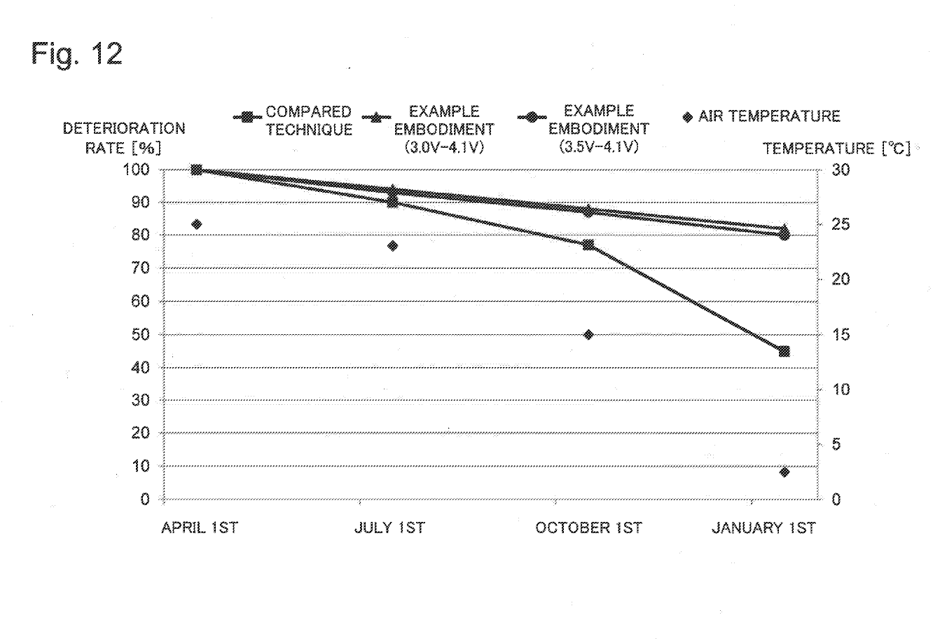

FIG. 12 is a diagram illustrating comparison of the measurement results of different measurement ranges.

As illustrated in FIG. 12, for the information processing device 20 of the present example embodiment, results of the deterioration rate in a first voltage interval (3.5 V to 4.1 V), and the deterioration rate in a second voltage interval (3.0 V to 4.1 V: the entire ordinary use range) were substantially equal. This is because, although not illustrated, results of measurement of the capacity of the information processing device 20 were substantially equal. Thus, the information processing device 20 can accurately calculate the deterioration rate of the entire storage battery on the basis of measurement of an arbitrarily given voltage section. That is, the information processing device 20 was able to realize the accurate measurement even though the voltage range to be measured was narrowed to reduce the measurement time.

### Description of Advantageous Effects

The information processing device 20 according to the present example embodiment can obtain an advantageous effect that the information processing device 20 shortens the measurement time, in addition to the advantageous effects of the first example embodiment. Furthermore, the information processing device 20 can obtain an advantageous effect that the information processing device 20 calculates the deterioration rate.

The reason is as follows.

It is because the information processing device 20 measures the capacity by using a voltage range for measurement which is narrower than the voltage range in use.

Furthermore, it is because the deterioration rate of the electricity storage unit 101 is calculated on the basis of the early capacity and the measured value of capacity calculated by the capacity computation unit 103 of the information processing device 20.

### Third Example Embodiment

The information processing device 10 in the first example embodiment and the information processing device 20 in the second example embodiment measure the capacity by using charges. However, as for the information processing device 10 and the information processing device 20, capacity may be measured by using discharge. Therefore, an example embodiment that uses discharges will be described as a third example embodiment.

Hereinafter, with reference to the drawings, the third example embodiment according to the present invention will be described.

[Description of Construction]

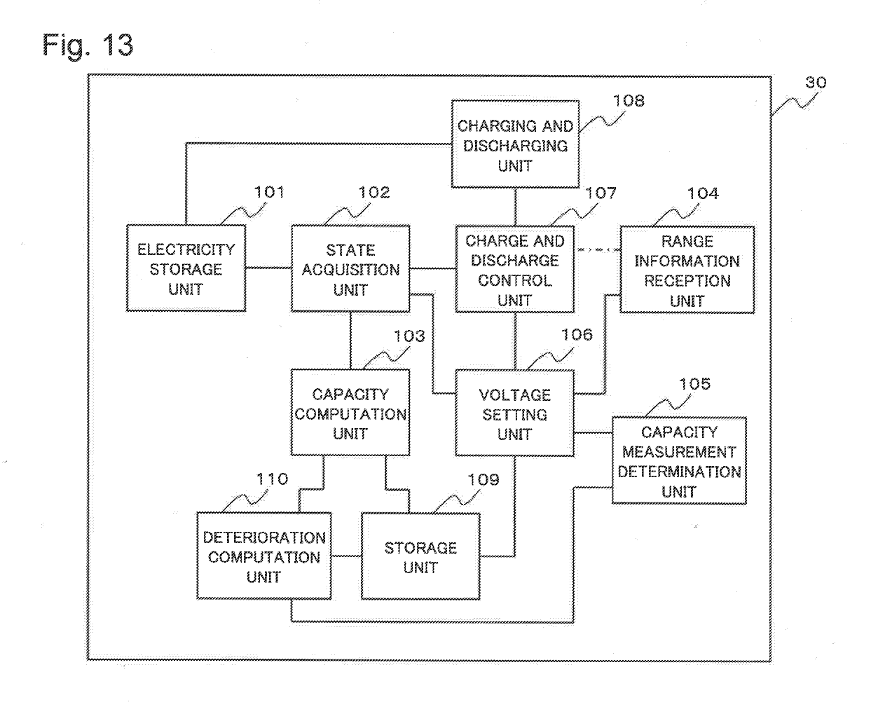

FIG. 13 is a block diagram illustrating an example of a construction of an information processing device 30 according to the third example embodiment. The construction of the information processing device 30 is the same as the information processing device 20, and detailed description of the construction will be omitted. Note that the information processing device 30 may be realized by using the computer illustrated in FIG. 6.

[Description of Operations]

Next, operations of the information processing device 30 will be described.

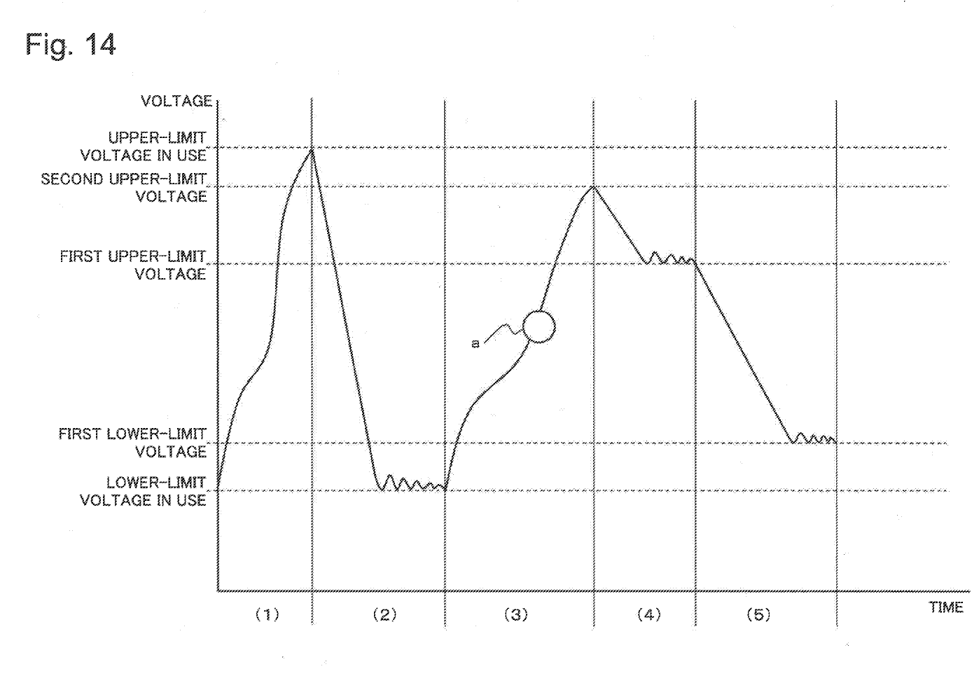

FIG. 14 is a diagram illustrating an example of the charging and discharging for the capacity measurement according to the third example embodiment. FIG. 14 is different from FIG. 8 in the direction of change in voltage. Furthermore, FIG. 14 illustrates the second upper-limit voltage instead of the second lower-limit voltage. This is because the present example embodiment uses discharging for measurement of the capacity. As illustrated in FIG. 14, in the present example embodiment, the second upper-limit voltage is an “upper-side voltage (upper voltage)”, the first upper-limit voltage is an “intermediate voltage (middle voltage)”, and the first lower-limit voltage is a “lower-side voltage (lower voltage)”.

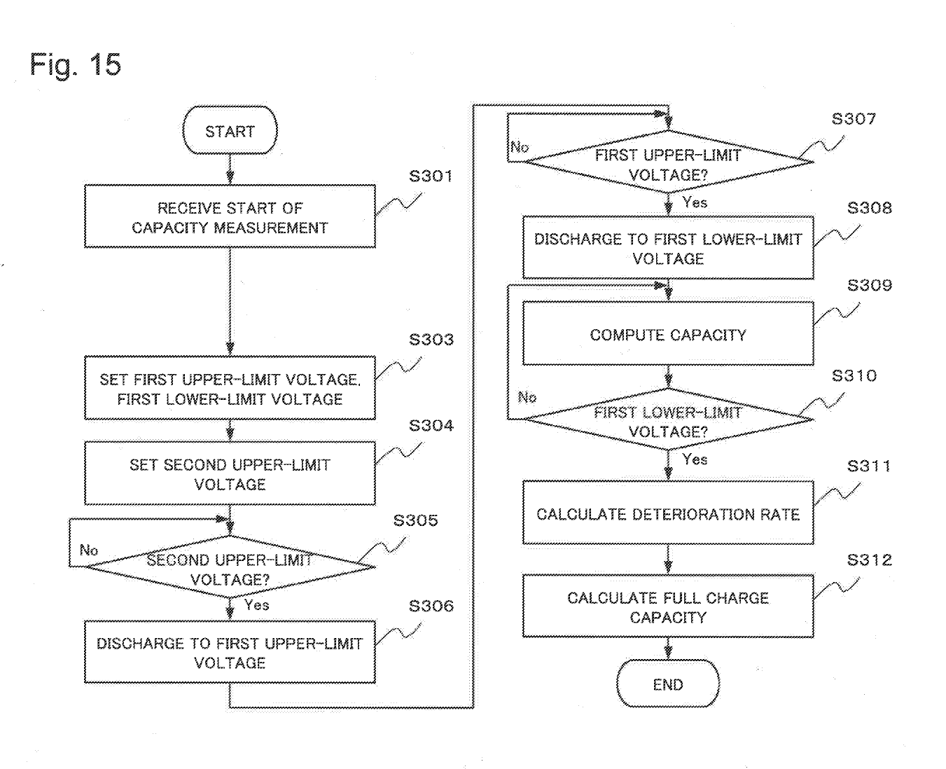

FIG. 15 is a flowchart illustrating an example of processing of the information processing device 30 according to the third example embodiment. As illustrated in FIG. 15, as for the operation of the information processing device 30, the second lower-limit voltage in steps S204 and S205 in FIG. 9 is replaced with the second upper-limit voltage in steps S304 and S305. Furthermore, as for the operation of the information processing device 30, the first lower-limit voltage in steps S206 and S207 in FIG. 9 is replaced with the first upper-limit voltage in steps S306 and S307. Furthermore, as for the operation of the information processing device 30, the first upper-limit voltage in steps S208 and S209 in FIG. 9 is replaced with the first lower-limit voltage in steps S308 and S308. Furthermore, the voltage setting unit 106 calculates the first upper-limit voltage in step S303. The other operations are substantially the same as in the second example embodiment. In other words, because the present example embodiment employs discharging instead of charging in the measurement. That is, the operation of the information processing device 30 of the present example embodiment is what is obtained by replacing charging with discharging in the operation of the information processing device 20 of the second example embodiment.

Therefore, hereinafter, descriptions of the same operations as in the second example embodiment will be omitted and operations specific to the third example embodiment will be described.

In step S303, the voltage setting unit 106 calculates the first lower-limit voltage. For example, the voltage setting unit 106 calculates a first lower-limit voltage that satisfies formula 5 illustrated below that corresponds to the formula 2.

The first lower-limit voltage≦(the first upper-limit voltage−(the internal resistance of the electricity storage unit 101×the discharge current value)) [Formula 5]

In step S304, the voltage setting unit 106 calculates the second upper-limit voltage. The second upper-limit voltage needs to be such a voltage that at least the open-circuit voltage of the electricity storage unit 101 does not go below the first upper-limit voltage. This is because when the open-circuit voltage of the electricity storage unit 101 is lower than the first upper-limit voltage, the CCCV discharging to the first upper-limit voltage cannot be executed. Thus, the voltage setting unit 106, for example, calculates a second upper-limit voltage that satisfies formula 6 indicated below that corresponds to formula 1.

The second upper-limit voltage≧(the first upper-limit voltage+(the internal resistance of the electricity storage unit 101×the charge current value)+(the internal resistance of the electricity storage unit 101×the discharge current value)) [Formula 6]

However, the method for determining the second upper-limit voltage does not need to be limited to this.

Then, the charging and discharging unit 108 charges the electricity storage unit 101 to the second upper-limit voltage on the basis of an instruction from the charge and discharge setting unit 107 (step S305).

Next, the charging and discharging unit 108, on the basis of an instruction from the charge and discharge setting unit 107, performs the CCCV discharging of the electricity storage unit 101 to the first upper-limit voltage (steps S306 and S307).

Then, the charging and discharging unit 108, on the basis of an order from the charge and discharge setting unit 107, performs the CCCV discharging of the electricity storage unit 101 to the first lower-limit voltage (step S308).

The capacity computation unit 103, on the basis of the current having flown between the first upper-limit voltage and the first lower-limit voltage, calculates a measured value of the capacity (full charge capacity) of the electricity storage unit 101 (step S309).

The subsequent operations are the same as those in the second example embodiment.

Note that in the information processing device 30 of the present example embodiment, the discharging does not need to be limited to CCCV discharging. For example, the information processing device 30 may employ CP discharging or pulse discharging instead of CC discharging. Alternatively, the information processing device 30 may employ variable-rate discharging as the discharging.

### Description of Advantageous Effects

Thus, the present example embodiment can obtain substantially the same advantageous effects as the second example embodiment.

The reason is as follows.

It is because although the information processing device 30 of the present example embodiment employs the current of the discharging instead of the charging in the information processing device 20 of the second example embodiment, the measurement of the capacity based on the current of the discharging allows calculation of substantially the same measurement results as the measurement of the capacity based on the current of the charging.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2014-181340, filed on Sep. 5, 2016, the disclosure of which is incorporated herein in its entirety by reference.

### REFERENCE SINGS LIST

10 Information processing device
11 Information processing device
12 Information processing device
20 Information processing device
30 Information processing device
60 Information processing device
101 Electricity storage unit
102 State acquisition unit
103 Capacity computation unit
104 Range information reception unit
105 Capacity measurement determination unit
106 Voltage setting unit
107 Charge and discharge control unit
108 Charging and discharging unit
109 Storage unit
110 Deterioration computation unit
610 CPU
620 ROM
630 RAM
640 Internal storage device
650 IOC
660 Input appliance
670 Display appliance
680 NIC
700 Storage medium

1. An information processing device comprising:
a reception unit which receives a state of an electricity storage unit which stores electric power;
a charge and discharge control unit which controls charging in a charging period that includes a first period in which charging is performed from a second lower-limit voltage to a first lower-limit voltage and a second period in which charging is performed from the first lower-limit voltage to a first upper-limit voltage; and
a capacity computation unit which calculates a capacity of the electricity storage unit, based on the state in the second period.

2. The information processing device according to claim 1, further comprising:
a voltage setting unit which calculates the second lower-limit voltage, based on the state and the first lower-limit voltage.

3. (canceled)

4. (canceled)

5. The information processing device according to claim 1, wherein
the charging period and the discharging period include, between the first period and the second period, a period in which charging or discharging is not performed.

6. The information processing device according to claim 1, wherein
the charge and discharge unit instructs charging or discharging at a constant current and a constant voltage.

7. (canceled)

8. An information processing method for an information processing device, the method comprising:
receiving a state of an electricity storage unit which stores electric power;
controlling charging of the electricity storage unit in a charging period that includes a first period in which charging is performed from a second lower-limit voltage to a first lower-limit voltage and a second period in which charging is performed from the first lower-limit voltage to a first upper-limit voltage; and
calculating a capacity of the electricity storage unit, based on the state in the second period.

9. A computer readable non-transitory recording medium embodying a program, the program causing a computer to perform a method, the method comprising:
receiving a state of an electricity storage unit which stores electric power;
controlling charging of the electricity storage unit in a charging period that includes a first period in which charging is performed from a second lower-limit voltage to a first lower-limit voltage and a second period in which charging is performed from the first lower-limit voltage to a first upper-limit voltage; and
calculating a capacity of the electricity storage unit, based on the state in the second period.
